(19) United States
(12) Patent Application Publication
(10) Pub. No.: US 2013/0264603 A1
(43) Pub. Date: Oct. 10, 2013

(54) SURFACE-MOUNTING LED CHIP

(71) Applicant: ADVANCED OPTOELECTRONIC TECHNOLOGY, INC., Hsinchu Hsien (TW)

(72) Inventors: HSIN-CHIANG LIN, Hsinchu (TW); PIN-CHUAN CHEN, Hsinchu (TW)

(73) Assignee: ADVANCED OPTOELECTRONIC TECHNOLOGY, INC., Hsinchu Hsien (TW)

(21) Appl. No.: 13/723,210

(22) Filed: Dec. 21, 2012

(30) Foreign Application Priority Data
Apr. 9, 2012 (CN) 201210100995X

(51) Int. Cl. H01L 33/36

(52) U.S. Cl. CPC H01L 33/36
USPC 257/99

(57) ABSTRACT

An LED (light emitting diode) chip includes a semiconductor. The semiconductor includes a main emitting surface on a top surface and a mounting surface on a bottom surface thereof. The LED chip further includes a P-type electrode and an N-type electrode protruding from the semiconductor, a first electrode layer extending from the P-type electrode to the mounting surface, a second electrode layer extending from the N-type electrode to the mounting surface and an insulating layer insulating the first electrode layer and the second electrode from the semiconductor. The first and second electrode layers are for surface mounting to a substrate. Each of the P-type and N-type electrodes includes a plurality of interdigital structures.

### BACKGROUND

1. Technical Field

The present disclosure relates to a lighting device, and more particularly, to an LED chip which can be surface mounted to a substrate while have a good current distribution through the LED chip.

2. Description of Related Art

LEDs (Light-Emitting Diodes) have many advantages, such as high luminosity, low operational voltage, low power consumption, compatibility with integrated circuits, easy driving, long term reliability, and environmental friendliness. Such advantages have promoted the wide use of the LEDs as a light source. LED chips each are commonly electrically connected to a substrate via positive and negative electrodes thereof. In order to increase electrical conduction, positive and negative electrodes of the LED chip each are made in the form of a comb-shaped electrode. However, a short circuit of the positive and negative electrodes of the LED chip may occur when surface mounting the LED chip to the substrate, due to too close relationship between the fingers of the comb-shaped electrodes. During the surface mounting, the solder on the fingers of one of the comb-shaped electrode can easily overflow to the fingers of the other comb-shaped electrode of the LED chip to cause the short circuit of the positive and negative electrodes of the LED chip.

What is needed, therefore, is an LED chip which can overcome the limitations described above.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a cross section of an LED chip in accordance with an embodiment of the present disclosure.

FIG. 2 is a top view of the LED module of FIG. 1, wherein an insulating layer of the LED chip is removed for clarity.

FIG. 3 is similar to FIG. 1, showing the LED chip attached to external electrodes.

### DETAILED DESCRIPTION OF THE EMBODIMENTS

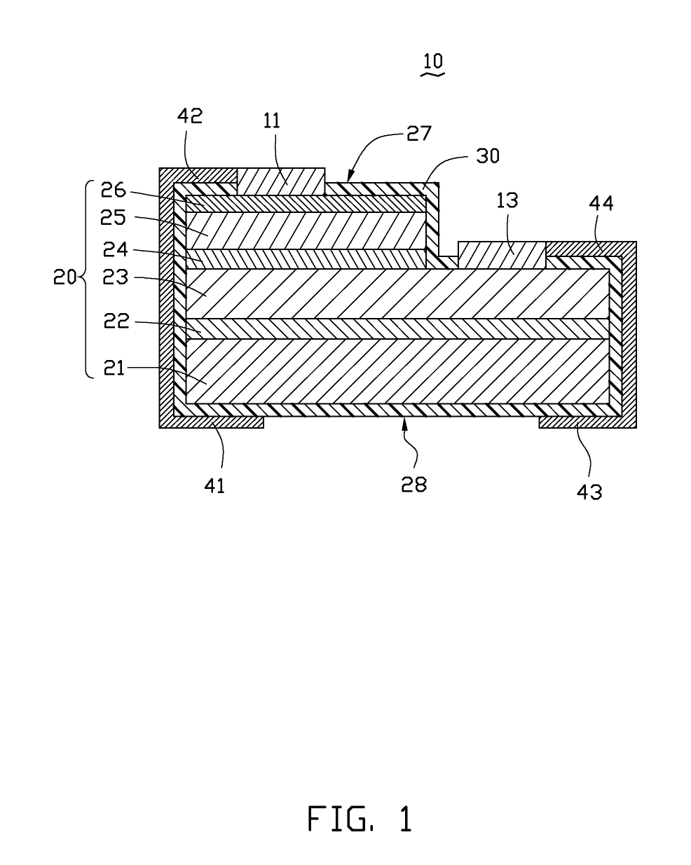

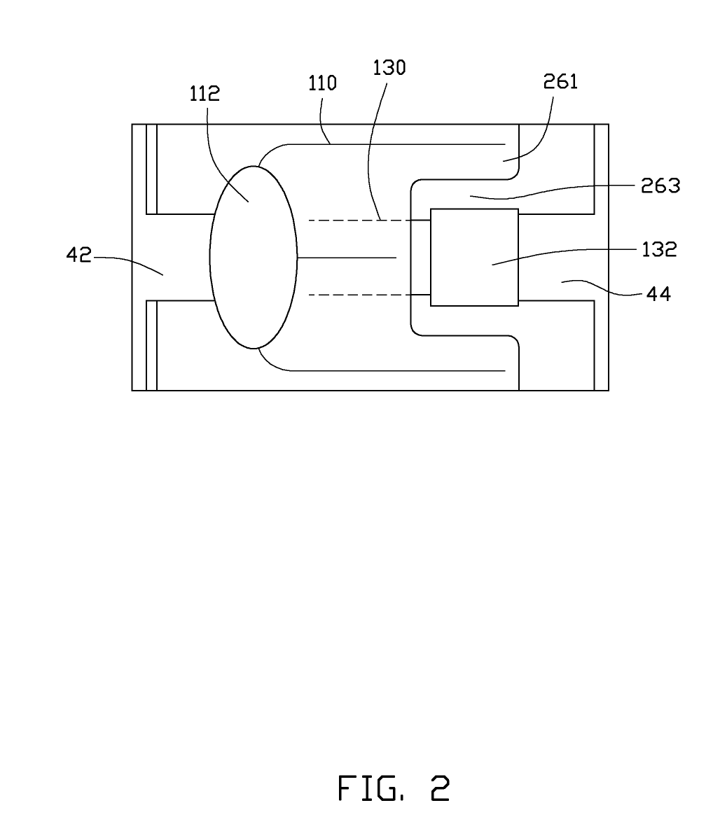

Referring to FIGS. 1-2, an LED (light emitting diode) chip 10 in accordance with an embodiment of the present disclosure is shown. The LED chip 10 includes a P-type electrode 11, an N-type electrode 13, a semiconductor light emitting structure 20, an insulating layer 30, a first electrode layer 42 and a second electrode layer 44.

The semiconductor light emitting structure 20 includes, in sequence from bottom to top, a substrate 21, a buffer layer 22, an N-type semiconductor layer 23, an active layer 24, a P-type semiconductor layer 25 and a conductive layer 26. The substrate 21 is made of materials such as silicone, silicone carbide or sapphire. In this embodiment, the N-type semiconductor layer 23 and the P-type semiconductor layer 25 are both GaN semiconductor layers, and the P-type electrode 11 and the N-type electrode 13 are both made of conductive metal materials. A main light emitting surface 27 is defined on a top surface of the LED chip 10, which is a top surface of the insulating layer 30, and a mounting surface 28 is defined on a bottom surface thereof, which is a bottom surface of the insulating layer 30 on a bottom of the substrate 21. The substrate 21 and the buffer layer 22 can be removed so that the mounting surface 28 is a bottom surface of the insulating layer 30 on a bottom of the N-type semiconductor layer 23. Similarly, the conductive layer 26 can be removed so that the main light emitting surface 27 is a top surface of the insulating layer 30 on a top of the P-type semiconductor layer 25.

The buffer layer 22 is thinner than the substrate 21 and completely covers the substrate 21 to reduce lattice mismatch between the N-type semiconductor layer 23 and the substrate 21. The N-type semiconductor layer 23 completely covers the buffer layer 22. The N-type electrode 13 protrudes on a right portion of the N-type semiconductor layer 23. The N-type electrode 13 is an interdigital electrode including a main portion 132 and a plurality of interdigital structures 130 extending leftward from the main portion 132. In this embodiment, the N-type electrode 13 includes two interdigital structures 130 extending in parallel. The two interdigital structures 130 may have fine needle shape and cover only a small portion of the N-type semiconductor layer 23. The active layer 24 covers a left portion of the N-type semiconductor layer 23 and left portions of the interdigital structures 130 of the N-type electrode 13. The active layer 24 includes a right portion with two protrusions and a concavity (not labeled). The right portion with the two protrusions and the concavity of the active layer 24 has a profile coincidental with that of the conductive layer 26 whose right portion also includes two protrusions 261 and a concavity 263 as shown in FIG. 2. The N-type electrode 13 is received in the concavity of the active layer 24. The two protrusions of the active layer 24 are respectively located at and spaced from a front side and a back side of the N-type electrode 13. The two protrusions cover a part of the right portions of the N-type semiconductor layer 23.

The P-type semiconductor layer 25 completely covers the active layer 24. The P-type semiconductor layer 25 also forms two protrusions and a concavity at a right portion thereof, which has a profile coincidental with that of the two protrusions 261 and the concavity 263 of the conductive layer 26. The conductive layer 26 completely covers the P-type semiconductor layer 25. The P-type electrode 11 protrudes on a left portion of the conductive layer 26. The P-type electrode 11 is an interdigital electrode including a main portion 112 and a plurality of interdigital structures 110 extending rightward from the main portion 112. In this embodiment, the P-type electrode 11 includes three interdigital structures 110 extending in parallel corresponding to the interdigital structures 130 of the N-type electrode 13. As shown in FIG. 2, the two interdigital structures 130 of the N-type electrode 13 and the three interdigital structures 110 of the P-type electrode 11 are interdigitated (alternated) with each other along a front-to-rear direction of the LED chip 10. The interdigital structures 130 of the N-type electrode 13 and the interdigital structures 110 of the P-type electrode 11 are in ohmic contact with the N-type semiconductor layer 23 and the P-type semiconductor layer 25, respectively. The interdigital structures 110 of the P-type electrode 11 located correspondingly over the two protrusions 261 of the conductive layer 26 are longer than the interdigital structure 110 extending correspondingly toward the concavity 263 of the conductive layer 26. The conductive layer 26 is made of transparent conductive materials and completely covers the P-type semiconductor layer 25.

The insulating layer 30 covers all surfaces of the semiconductor layer 20 so that only the P-type electrode 11 and the N-type electrode 13 are exposed outside the insulating layer 30. The insulating layer 30 is made of transparent insulated material such as SiO₂. A thickness of the insulating layer 30 is less than half a thickness of the P-type electrode 11 and the N-type electrode 13. It is understood that the main light emitting surface 27 is a top surface of the insulating layer 30 and the mounting surface 28 is a bottom surface of the insulating layer 30 due to the insulating layer 30 covers all surfaces of the semiconductor layer 20. Both the P-type electrode 11 and the N-type electrode 13 protrude from the insulating layer 30. The first electrode layer 42 extends from a left side of the P-type electrode 11 and covers a left surface of the insulating layer 30. The second electrode layer 44 extends from a right side of the N-type electrode 13 and covers a right surface of the insulating layer 30. A bottom surface of the first electrode layer 42 forms a P-type connecting electrode 41. A bottom surface of the second electrode layer 44 forms an N-type connecting electrode 43. Due to the insulating layer 30, the first electrode layer 42 and the second electrode layer 44 are insulated from the layers of the semiconductor light emitting structure 20 and only electrically connect the P-type electrode 11 and the N-type electrode 13, respectively. In another embodiment, the first electrode layer 42 and the second electrode layer 44 may extend to the bottom face of the insulating layer 30 through a front side surface and a back side surface of the insulating layer 30, without covering the left surface and the right surface of the insulating layer 30. A total thickness of the insulating layer 30 and the first electrode layer 42 is equal or less than the thickness of the P-type electrode 11. A total thickness of the insulating layer 30 and the second electrode layer 42 is equal or less than the thickness of the P-type electrode 13.

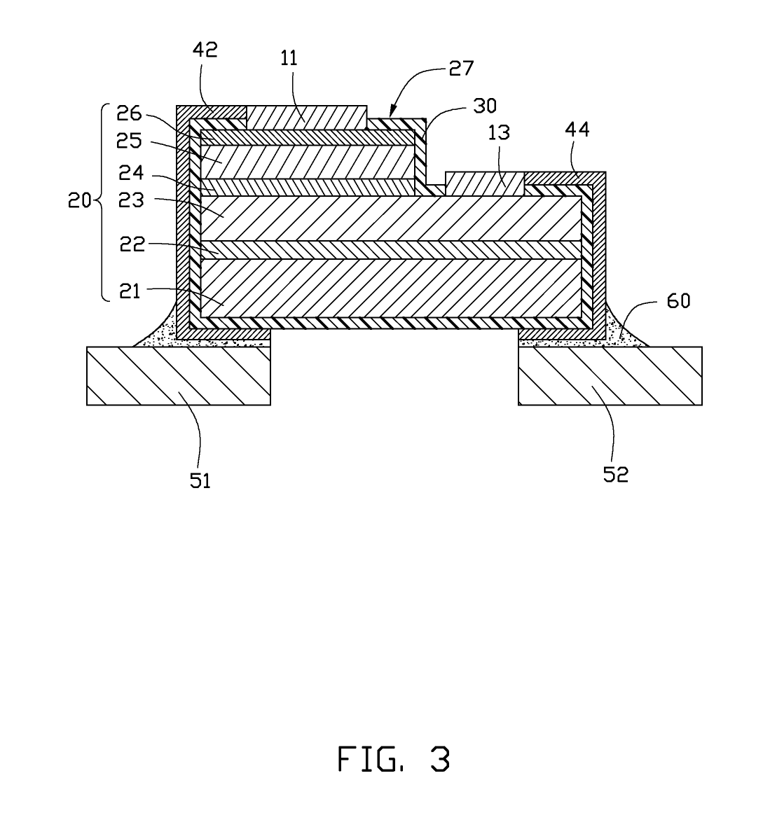

Referring to FIG. 3, the LED chip 10 is attached to a pair of external electrodes in a manner that the first electrode layer 42 connects a first external electrode 51 and the second electrode layer 44 connects a second external electrode 52. In this embodiment, a connecting layer 60 is provided between the first electrode layer 42 and the first external electrode 51, and between the second electrode layer 44 and the second external electrode 52. The connecting layer 60 is made of solder.

Since the LED chip 10 includes the first electrode layer 42 and the second electrode layer 44 extending from the top surface of the LED chip 10 to the bottom surface thereof, the LED chip 10 can be conveniently surface-mounted to a substrate, for example, a printed circuit board (not shown).

In other embodiments, the P-type electrode 11 and the N-type electrode 13 can protrude from the left surface and the right surface of the semiconductor light emitting structure 20. Thus the first electrode layer 42 and the second electrode layer 44 can extend from the left surface and the right surface of the semiconductor light emitting structure 20 to the bottom surface thereof.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. An LED (light emitting diode) chip comprising:
a semiconductor comprising a main light emitting surface on a top surface and a mounting surface on a bottom surface thereof;
a P-type electrode and an N-type electrode protruding from the top surface of the semiconductor, each of the P-type and N-type electrodes having a plurality of interdigital structures extending on the top surface of the semiconductor;
a first electrode layer extending from the P-type electrode to the mounting surface and a second electrode layer extending from the N-type electrode to the mounting surface, the first and second electrode layers being configured for surface mounting to a substrate; and
an insulating layer insulating the first electrode layer and the second electrode from the semiconductor.

2. The LED chip of claim 1, wherein the semiconductor comprises an N-type semiconductor layer, an active layer and a P-type semiconductor layer, the P-type electrode protruding from the P-type semiconductor layer, and the N-type electrode protruding from the N-type semiconductor layer.

3. The LED chip of claim 2, wherein the semiconductor comprises a substrate supporting the N-type semiconductor layer, the active layer and the P-type semiconductor layer thereon.

4. The LED chip of claim 3, wherein the semiconductor further comprises a buffer layer between the substrate and the N-type semiconductor layer for lessening a lattice mismatch between the substrate and the N-type semiconductor layer.

5. The LED chip of claim 3, wherein the semiconductor further comprises a conductive layer on the P-type semiconductor layer.

6. The LED chip of claim 1, wherein the insulating layer covers a first side surface and a second side surface of the semiconductor.

7. The LED chip of claim 6, wherein the first electrode layer extends on the insulating layer covering the first side surface, the second electrode layer extends on the insulating layer covering the second side surface.

8. The LED chip of claim 2, wherein the P-type electrode and the N-type electrode each comprise a main portion, the interdigital structures extending from the main portion.

9. The LED chip of claim 8, wherein a number of the interdigital structures of the P-type electrode is three, and a number of the interdigital structures of the N-type electrode is two.

10. The LED chip of claim 9, wherein the three interdigital structures of the P-type electrode extend in parallel from the main portion of the P-type electrode towards the N-type electrode.

11. The LED chip of claim 9, wherein the two interdigital structures of the N-type electrode extend in parallel from the main portion of the N-type electrode towards the P-type electrode.

12. The LED chip of claim 11, wherein the three interdigital structures of the P-type electrode and the two interdigital structures of the N-type electrode are interdigitated with each other.

13. The LED chip of claim 12, wherein each of the active layer and the P-type semiconductor layer comprises two protrusions and a concavity between the two protrusions, the main portion of the N-type electrode being received in the concavities of the active layer and the P-type semiconductor layer.

14. The LED chip of claim 13, wherein the interdigital structures of the P-type electrode located correspondingly over the two protrusions of the P-type semiconductor layer are longer than the interdigital structure of the P-type electrode extending correspondingly toward to the concavity of the P-type semiconductor layer.

15. The LED chip of claim 13, wherein the two interdigital structures of the N-type electrode extend correspondingly under the concavity of the P-type semiconductor layer toward the main portion of the P-type electrode.

16. The LED chip of claim 15, wherein the two interdigital structures of the N-type electrode extend between the active layer and the N-type semiconductor layer.

17. The LED chip of claim 6, wherein the first electrode layer extending from a first side of the P-type electrode, the second electrode layer extending from a second side of the N-type electrode.

18. The LED chip of claim 17, wherein a thickness of the insulating layer is less than half a thickness of each of the P-type electrode and the N-type electrode.

19. The LED chip of claim 17, wherein a total thickness of the insulating layer and the first electrode layer is equal or less than the thickness of the P-type electrode.
